(19) United States
(12) Patent Application Publication
(10) Pub. No.: US 2004/0065949 A1
(43) Pub. Date: Apr. 8, 2004

(54) [SOLDER BUMP]

(76) Inventors: William Tze-You Chen, Endicott, NY (US); Ho-Ming Tong, Taipei (TW); Chun-Chi Lee, Kaohsiung (TW); Su Tao, Kaohsiung (TW); Jeng-Da Wu, Kaohsiung Hsien (TW); Chih-Huang Chang, Tainan Hsien (TW); Po-Jen Cheng, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,758

(22) Filed: May 6, 2003

(30) Foreign Application Priority Data
Oct. 8, 2002 (TW) 91123177

(51) Int. Cl. H01L 23/48

(52) U.S. Cl. 257/692

(57) ABSTRACT

A flip chip interconnect structure is formed on a bump pad of a chip, and includes an under bump metallurgy (UBM) formed on the bump pad, and a solder bump formed on the UBM. The solder bump includes tin and is further doped with metallic particles that are capable of reacting with tin in the solder bump to from an inter-metallic compound due to a thermal effect produced in use of a later fabrication process or an operation on the chip. Furthermore, the material of the metal particles is selected from a group consisting of copper, silver and nickel.

### CROSS REFERENCE TO RELATED APPLICATIONS

This application claims the priority benefit of Taiwan application serial no. 91123177, filed Oct. 8, 2002, the full disclosure of which is incorporated herein by reference.

### BACKGROUND OF INVENTION

1. Field of the Invention

The present invention relates to a solder bump. More specifically, the present invention relates to a solder bump that enhances the bonding to a bump pad of a chip.

2. Description of the Related Art

In flip chip interconnect technology, a plurality of bump pads are usually formed in array on an active surface of the semiconductor chip, each bump pad being covered with an UBM (under bump metallurgy). A conductive bump is formed on each bump pad, and the chip is electrically connected on a substrate or a printed circuit board (PCB) via the conductive bumps. A flip chip interconnect structure is particularly advantageous for the reason that it allows a semiconductor package with high pin count, a reduced package area and shortened signal transmission paths.

FIG. 1 is a schematic enlarged view of a conventional flip chip interconnect structure. As illustrated, a flip chip interconnect structure 100 includes a chip 110 and a plurality of solder bumps 124 (only one solder bump is shown). The chip 110 has an active surface 112, a passivation layer 114 and a plurality of bump pads 116 (only one bump pad is shown) on the active surface 112. The passivation layer 114 exposes a portion of the bump pad 116. Furthermore, a UBM 122 is formed on the bump pad 116, and a solder bump 124 is formed on the UBM 122. The solder bump 124 is used as an external connection to the chip 110.

The conventional UBM 122 usually includes an adhesive layer 122a, a barrier layer 122b, and a wettable layer 122c. The adhesive layer 122a increases the bonding between the bump pad 116 and the barrier layer 122b. The material of the adhesive layer 122a includes, for example, aluminum and titanium. The barrier layer 122b prevents diffusion of the underlying metal. The material of the barrier layer 122b includes, for example, a nickel vanadium alloy. The wettable layer 122c increases the wettability of the UBM 122 to the solder bump 124. The material of the wettable layer 122c includes copper. Tin lead alloy is usually used as a solder material because of its good solderability. However, the discharge of lead-containing substances seriously pollutes the environment. Therefore, a lead free solder material has been proposed to replace the conventional lead-containing solder material. Herein, whether with-lead solder or lead-free solder both includes tin.

When the wettable layer 122c of the UBM 122 contains copper as a main component, tin in the solder bump 124 easily reacts with copper in the wettable layer 122c during the reflow process, which forms an inter-metallic compound (IMC) such as Cu₆Sn₅. Then an IMC layer (not shown) is formed between the wettable layer 122c and the solder bump 124. When the barrier layer 122b of the UBM 122 contains nickel vanadium alloy as a main component, tin in the solder bump 124 reacts with copper in the wettable layer 122c during the reflow process to form the IMC Cu₆Sn₅. Then, tin in the solder bump 124 also reacts with nickel in the barrier layer 122b to form another IMC, i.e. Ni₃Sn₄. Ni₃Sn₄ formed by the long-term reaction of tin and nickel has a structure of discontinuous blocks, which makes the solder bump 124 peel off from the UBM 122.

### SUMMARY OF INVENTION

Therefore, it is a main object of the present invention to provide a flip chip interconnect structure that can slow down the formation of the discontinuous block structure in the barrier layer so that this latter maintains its original structural strength. The flip chip interconnect structure is therefore more reliable.

According to one aspect of the present invention, a flip chip interconnect structure, formed on a bump pad of a chip, includes an under bump metallurgy (UBM) formed on the bump pad, and a solder bump formed on the UBM. The solder bump includes tin, and is further doped with metallic particles that are capable of reacting with tin in the solder bump to form an inter-metallic compound (IMC) due to a thermal effect produced in use of a later fabrication process or an operation on the chip. Furthermore, the metallic particles are selected from a group consisting of copper, silver and nickel.

According to another aspect of the present invention, a solder bump includes tin, and is further doped with metallic particles that are capable of reacting with tin in the solder bump to from an IMC to a thermal effect produced in use of a later fabrication process or an operation on the chip. The metallic particles are selected from a group consisting of copper, silver and nickel.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principle of the invention.

FIG. 1 is a sectional view of a conventional flip chip interconnect structure.

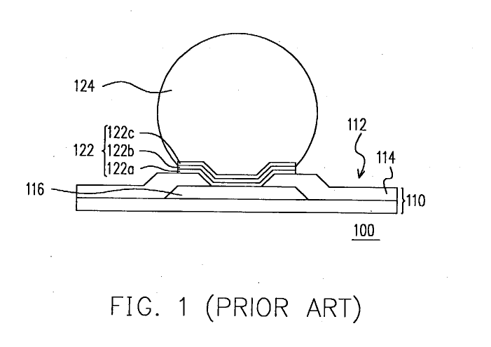

FIG. 2 is a sectional view of a flip chip interconnect structure according to one preferred embodiment of the present invention.

### DETAILED DESCRIPTION

Reference will now be made in detail to the preferred embodiments of the invention, examples of which are illustrated in the accompanying drawings. Whenever possible, the same reference numbers are used in the drawings and the description to refer to the same or like parts.

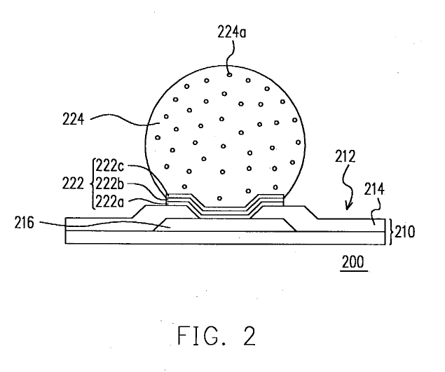

FIG. 2 is a sectional view of a flip chip interconnect structure according to one preferred embodiment of the present invention. A flip chip interconnect structure 200 (e.g. a semiconductor device or a divided wafer) includes a chip 210 (e.g. a substrate with a semiconductor circuit formed thereon) that has an active surface 212. A passivation layer 214 (or a dielectric layer) is formed over the active surface 212 and exposes a plurality of bump pads 216 thereon (only one is shown). A UBM 222 is formed on the bump pad 216, and a solder bump 224 is formed on the UBM 222. The solder bump 224 is used as a (bump) electrode of the chip 210.

The UBM 222 includes an adhesive layer 222a, a barrier layer 222b, and a wettable layer 222c. The adhesive layer 222a increases the bonding between the bump pad 216 and the barrier layer 222b. The material of the adhesive layer 222a includes, for example, aluminum and titanium. The barrier layer 222b prevents diffusion of the underlying metal of the adhesive layer 222a. The material of the barrier layer 222b includes, for example, a nickel vanadium alloy. The wettable layer 222c increases the wettability of the UBM 222 in respect of the solder bump 224. The material of the wettable layer 222c includes copper. The solder bump 224 is further doped with metallic particles 224a, which is described in detail further.

If the wettable layer 222c of the UBM 222 mainly includes copper and the barrier layer 222b of the UBM 222 mainly includes nickel vanadium alloy, once a thermal effect such as reflow is conducted, tin in the solder bump 224 reacts with copper in the wettable layer 222c to form an inter-metallic compound (Cu₆Sn₅). Tin in the solder bump 224 also reacts with nickel in the barrier layer 222b to form another IMC (Ni₃Sn₄). Ni₃Sn₄ formed by the long-term reaction of tin and nickel has a structure of discontinuous blocks, which makes the solder bump 224 peel off from the UBM 222.

In order to overcome the problem of the prior art, metallic particles 224a, as disclosed above, are distributed in the solder bump 224. This may be achieved by, for example, doping. The metallic particles 224a preferably include a metal that are capable of reacting with tin in the solder bump to form an IMC due to a thermal effect produced in use of a later fabrication process or an operation on the chip. The metallic particles 224a include, for example, copper, silver, and nickel. By doping the metallic particles 224a, the reaction speed between tin in the solder bump 224 and nickel in the barrier layer 222b decreases. Therefore, the formation of the discontinuous blocks in the barrier layer 222b is slowed down, and this latter substantially maintains a desired structural strength.

The solder bump 224 may be formed on the UBM 222 by, for example, printing or ball attachment methods. Various processes may be envisaged to form the metallic particles. In one example, the metallic particles 224a may be coated on the solder bump 224 during the formation of the solder bump. In another example, the metallic particles 224a may be mixed in a solder paste that is printed on the bump pad to form the solder bump 224.

As described above, the flip chip interconnect structure according to the invention is therefore characterized in that metallic particles are doped in the solder bump and the metallic particles are capable of reacting with tin in the solder bump to have an IMC due to a thermal effect produced in use of a later fabrication process or an operation on the chip. Tin in the solder bump therefore first reacts with the metallic particles. As a result, the formation of the discontinuous block structure in the barrier layer is slowed down so that the barrier layer substantially keeps a desired structural strength. Therefore, the strength of the bonding between the solder bump and the bump pad is not altered, and the flip chip interconnect structure is more reliable.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

1. A flip chip interconnect structure formed on a bump pad of a chip, the flip chip interconnect structure comprising:
an under bump metallurgy (UBM), formed on the bump pad; and
a solder bump, formed on the UBM, wherein the solder bump comprises tin, and is further doped with metallic particles that are capable of reacting with tin in the solder bump.

2. The flip chip interconnect structure of claim 1, wherein the material of the metal particles is selected from a group consisting of copper, silver and nickel.

3. The flip chip interconnect structure of claim 1, wherein the UBM comprises:
an adhesive layer, formed on the bump pad;
a barrier layer, formed on the adhesive layer; and
a wettable layer, formed between the barrier layer and the solder bump.

4. The flip chip interconnect structure of claim 3, wherein the material of the adhesive layer includes aluminum or titanium.

5. The flip chip interconnect structure of claim 3, wherein the material of the barrier layer includes nickel vanadium alloy.

6. The flip chip interconnect structure of claim 3, wherein the material of the wettable layer includes copper.

7. A solder bump in a flip chip interconnect structure is formed on a bump pad of a chip, wherein the solder bump comprises tin, and is further doped with metallic particles that are capable of reacting with tin in the solder bump.

8. The flip chip interconnect structure of claim 7, wherein the material of the metal particles is selected from a group consisting of copper, silver and nickel.

9. A semiconductor device having a bump electrode comprising:
a substrate having a dielectric layer formed thereon;
a bump pad on the substrate wherein at least a portion of the bump pad is exposed through the dielectric layer on the substrate;
an under bump metallurgy (UBM) formed on the bump pad; and
a solder bump formed on the UBM, wherein the solder bump comprises tin and is further doped with metallic particles that are capable of reacting with tin in the solder bump.

10. The semiconductor device of claim 9, wherein the material of the metal particles is selected from a group consisting of copper, silver and nickel.

11. The semiconductor device of claim 9, wherein the UBM comprises:
an adhesive layer, formed on the bump pad;
a barrier layer, formed on the adhesive layer; and
a wettable layer, formed between the barrier layer and the solder bump.

12. The semiconductor device of claim 11, wherein the material of the adhesive layer includes aluminum or titanium.

13. The semiconductor device of claim 11, wherein the material of the barrier layer includes nickel vanadium alloy.

14. The semiconductor device of claim 11, wherein the material of the wettable layer includes copper.

15. A wafer having at least one bump electrode comprising:
a substrate having a dielectric layer formed thereon;
a bump pad on the substrate wherein at least a portion of the bump pad is exposed through the dielectric layer on the substrate;
an under bump metallurgy (UBM) formed on the bump pad; and
a solder bump formed on the UBM, wherein the solder bump comprises tin and is further doped with metallic particles that are capable of reacting with tin in the solder bump.

16. The wafer of claim 15, wherein the material of the metal particles is selected from a group consisting of copper, silver and nickel.

17. The wafer of claim 15, wherein the UBM comprises:
an adhesive layer, formed on the bump pad;
a barrier layer, formed on the adhesive layer; and
a wettable layer, formed between the barrier layer and the solder bump.

18. The wafer of claim 17, wherein the material of the adhesive layer includes aluminum or titanium.

19. The wafer of claim 17, wherein the material of the barrier layer includes nickel vanadium alloy.

20. The wafer of claim 17, wherein the material of the wettable layer includes copper.
